(19) United States
(12) Patent Application Publication
(10) Pub. No.: US 2009/0085097 A1
(43) Pub. Date: Apr. 2, 2009

(54) METHODS OF FORMING NITRIDE STRESSING LAYER FOR REPLACEMENT METAL GATE AND STRUCTURES FORMED THEREBY

(76) Inventors: Lucian Shifren, Hillsboro, OR (US); Keith E. Zawadzki, Portland, OR (US)

Correspondence Address: INTEL/BSTZ;BLAKELY SOKOLOFF TAYLOR & ZAFMAN LLP, 1279 OAKMEAD PARKWAY, SUNNYVALE, CA, 94085-4040, US

(21) Appl. No.: 11/863,116

(22) Filed: Sep. 27, 2007

(51) Int. Cl. H01L 29/94; H01L 21/311

(52) U.S. Cl. 257/327; 438/702; 257/E29.345; 257/E21.249

(57) ABSTRACT

Methods and associated structures of forming a microelectronic device are described. Those methods may include removing residual dielectric material from a metal gate structure, and then forming a stress relief layer on a top surface and on a sidewall region of the metal gate structure. A stress is introduced into a channel region disposed beneath the metal gate structure.

### BACK GROUND OF THE INVENTION

Optimizing stress in NMOS/PMOS transistor structures can greatly improve performance in microelectronic devices utilizing such transistors. Introducing stress into the channel regions of such transistor structures may improve device drive performance.

### BRIEF DESCRIPTION OF THE DRAWINGS

While the specification concludes with claims particularly pointing out and distinctly claiming that which is regarded as the present invention, the advantages of this invention can be more readily ascertained from the following description of the invention when read in conjunction with the accompanying drawings in which:

FIGS. 1a-1h represent structures according to an embodiment of the present invention.

FIGS. 2a-2b represent graphs according to an embodiment of the present invention.

FIG. 3 represents a flow chart according to an embodiment of the present invention.

### DETAILED DESCRIPTION OF THE PRESENT INVENTION

In the following detailed description, reference is made to the accompanying drawings that show, by way of illustration, specific embodiments in which the invention may be practiced. These embodiments are described in sufficient detail to enable those skilled in the art to practice the invention. It is to be understood that the various embodiments of the invention, although different, are not necessarily mutually exclusive. For example, a particular feature, structure, or characteristic described herein, in connection with one embodiment, may be implemented within other embodiments without departing from the spirit and scope of the invention. In addition, it is to be understood that the location or arrangement of individual elements within each disclosed embodiment may be modified without departing from the spirit and scope of the invention. The following detailed description is, therefore, not to be taken in a limiting sense, and the scope of the present invention is defined only by the appended claims, appropriately interpreted, along with the full range of equivalents to which the claims are entitled. In the drawings, like numerals refer to the same or similar functionality throughout the several views.

Methods and associated structures of forming a microelectronic structure are described. Those methods may include removing residual dielectric material from a metal gate structure, and then forming a stress relief nitride on a top surface and on a sidewall region of the metal gate structure. A stress is introduced into a channel region disposed beneath the metal gate structure. Methods of the present invention enable the incorporation of a nitride stressing layer in a replacement metal gate MOS process for the purpose of improving drive performance.

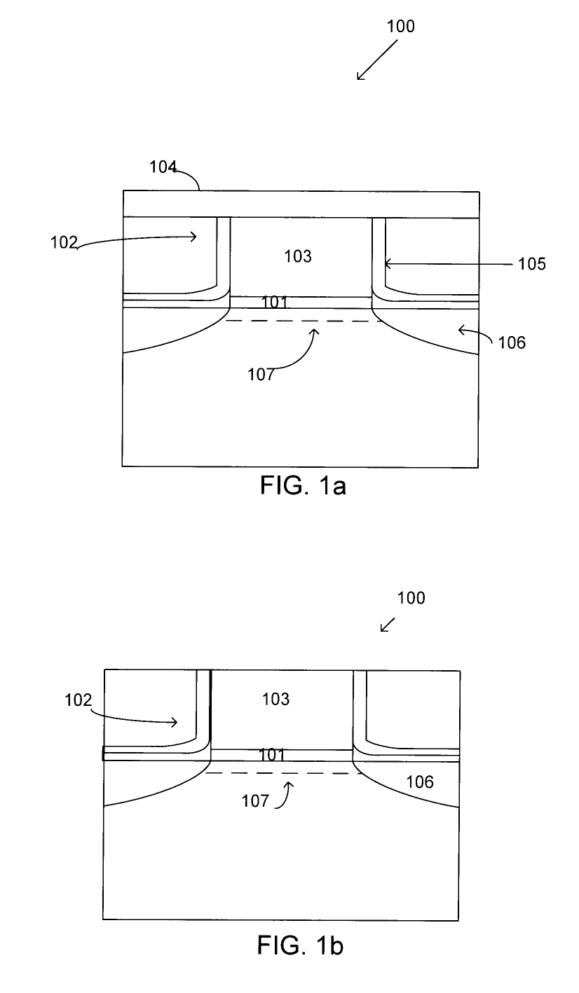

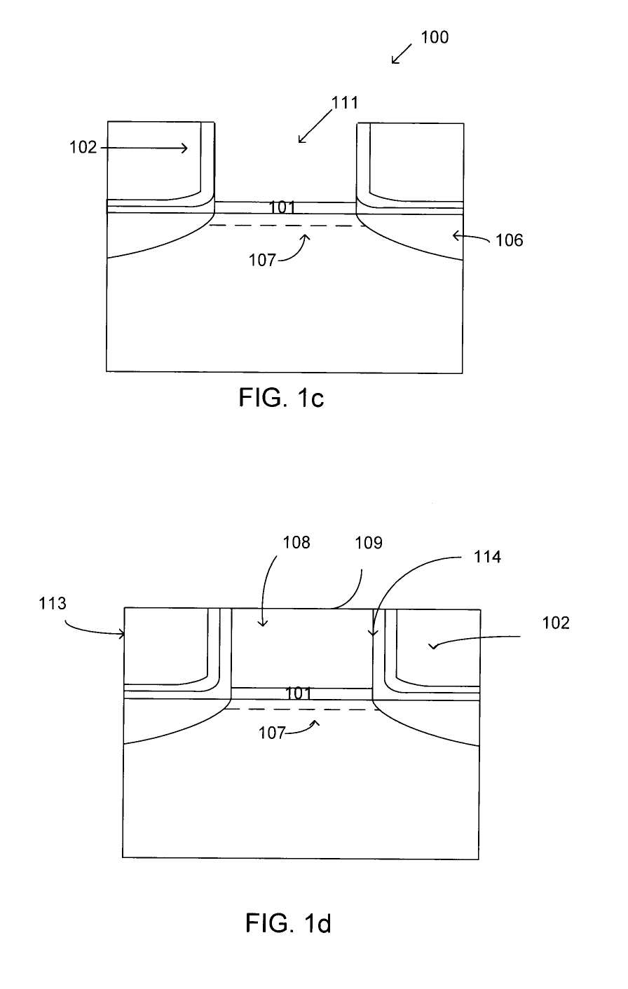

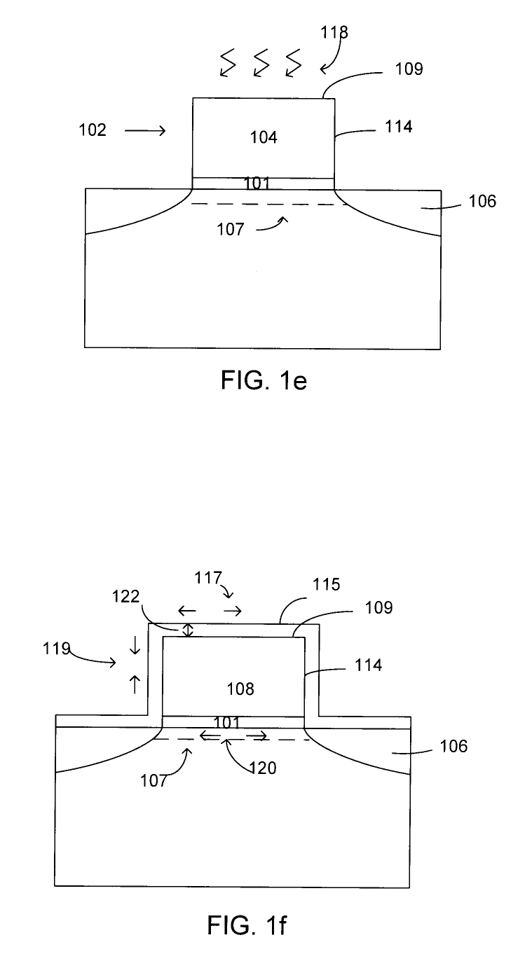

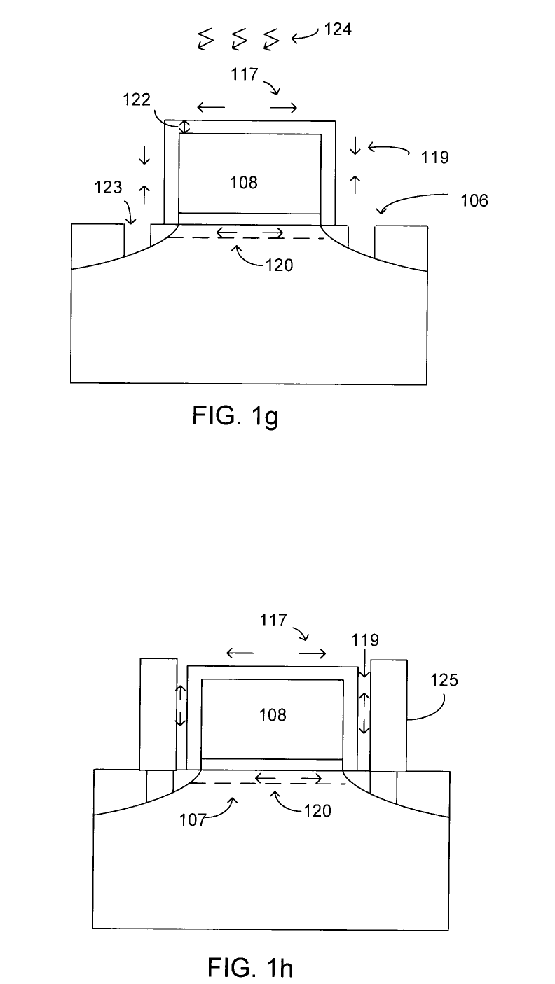

FIGS. 1a-1h illustrate an embodiment of a method of forming a microelectronic structure, such as a transistor structure, for example. FIG. 1a illustrates a cross-section of a portion of a transistor structure 100. The transistor structure 100 may comprise a portion of at least one of an NMOS transistor and a PMOS transistor, in some embodiments. The transistor structure 100 may comprise a gate region 102 that may comprise a gate oxide 101 and a gate 103.

The transistor structure 100 may also comprise a spacer region 105 and a channel region 107 located beneath the gate oxide region 101. The transistor structure 100 may further comprise a source/drain region 106, which may be located adjacent at least one side of the gate 103. The source/drain 106 regions may comprise silicon and/or silicon containing materials in some embodiments, but may comprise other materials in other embodiments, such as but not limited to silicon germanium materials.

In one embodiment, a nitride material 104 may be disposed on the gate 103. The nitride material 104 may be removed from the gate 103 by utilizing a removal process such as a polishing chemical mechanical polish (CMP) process, for example (FIG. 1b). In one embodiment, the gate 103 may comprise a polysilicon gate material. In one embodiment, the gate 103 may be removed by utilizing a removal process, such as a wet etch for example, to form an opening 111 in the transistor structure 100 (FIG. 1c). A metal gate 108 may then be formed in the opening 111 of the transistor structure 100 (FIG. 1d). In one embodiment, the metal gate 108 may comprise aluminum, titanium and nitride.

The gate region 102 may comprise residual materials 113, such as dielectric materials not limited to nitride and oxide films, for example. These materials 113 may be disposed on sidewalls 114 and a top surface 109 of the metal gate 103, for example. The materials 113 may be removed from the gate region 102, by utilizing a suitable etch process 118 (FIG. 1e). In one embodiment, the etch process 118 may be used to remove substantially all of the remaining nitride/oxide in between gate regions 102 of adjacent transistor structures 100, as well as removing the residual materials 113 from the top surface 109 and the sidewalls 114 of the metal gate 104.

In one embodiment, a stress relief layer 115 may be formed on the top surface 109 and on the sidewalls 114 of the metal gate 103 (FIG. 1f). In one embodiment, the stress relief layer 115 may comprise a dielectric layer, such as but not limited to a nitride stress relief layer 115. In one embodiment, the stress relief layer 115 may comprises a thickness 122 from about 5 nm to about 35 nm. In one embodiment, the stress relief layer 115 may comprise a dual layer, i.e., a first layer of a dielectric material disposed on a second layer of dielectric material. In one embodiment, the stress relief layer 115 may comprises a gate edge stop layer.

During the formation of the stress relief layer 115, the intrinsic stress of the stress relief layer 115 may result in stress being introduced into the transistor structure 100, including into the channel region 107. In one embodiment, a Sxx stress 117, a Syy stress 119 and a Szz stress (not shown) may be intrinsically present in the stress relief layer 115. In one embodiment, the Sxx stress 117 may comprise a tensile stress and the Syy stress 119 and Szz stresses may comprise compressive stresses.

These various stress components present in the stress relief nitride layer 115 may introduce a stress 120 into the channel region 107 disposed beneath the metal gate 104. The stress relief layer 115 may transfer stress into the channel 107, which in some embodiments may include NMOS/PMOS channel regions, and may thereby improve drive performance of the transistor. In one embodiment, the stress 120 may comprise a tensile stress, and may comprises about 200 to about 300 MPa in some cases, but will vary depending upon the particular application.

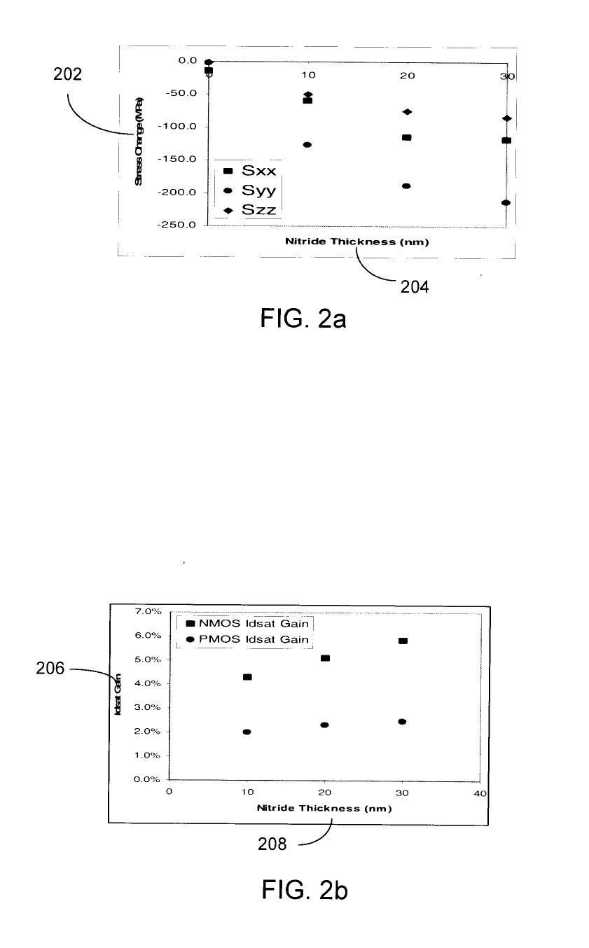

In one embodiment, a compressive Sxx stress 117 and tensile Syy stress 119 and Szz stresses may be beneficial for NMOS transistor performance. In another embodiment, compressive Sxx 117 and Syy 119 and tensile Szz may be beneficial for PMOS performance. In one embodiment, the Syy stress 117 may result in roughly twice the benefit to the device performance as Sxx stress 119 or Szz stress for NMOS transistors. FIG. 2a depicts stress change 202 in MPa for various nitride thicknesses 204. It can be seen that the magnitude and direction (i.e. compressive or tensile) of the stresses Sxx, Syy, Szz 117, 119 present in the stress relief layer 115 may be optimized by varying the nitride thickness, for example, according to the particular application. An optimized channel stress 120 in NMOS/PMOS devices may greatly improve drive performance of such transistors.

For the PMOS devices, the Syy stress 119 response may be somewhat weaker than the Sxx stress 117 and the Szz stress, but when added to the extra compressive Sxx stress 117 (which may exceed the compressive Szz stress) will result in a net gain. For NMOS transistors, a final stress state of the channel 107 may results in an overall stress enhancement equivalent to about 200 MPa to about 300 tensile Sxx stress 117, which is beneficial to the device performance (even though in some cases while the Sxx stress 117 may be compressive which is not generally favorable, the Szz stress component and the large increase in the Syy stress 117 will result in an overall stress benefit for NMOS devices). As a result of the optimization of the channel 107 stress by utilizing the various embodiments of the present invention, about a 6% gain in the metal gate NMOS device performance in terms of Idsat gain 206 (Idsat is the saturation current of a mosfet which is measured when the device Drain and Gate are both biased to VCC. Idsat gain is the gain between two different measured currents due to a change in devices, in this case stress. and about a 2% Idsat gain for the PMOS devices can be realized, as depicted in FIG. 2b for various nitride thicknesses 208.

In one embodiment, the source/drain region 106 may be etched 124 to form a trench contact opening 123 (referring back to FIG. 1g). In one embodiment, the etch 124 may comprise a trench contact etch process (TCN) 124. A trench contact material 125, which may comprise various metals such as but not limited to aluminum, copper and aluminum, according to the particular application, may then be formed in the trench contact opening 123 utilizing any suitable formation process (FIG. 1h). In one embodiment, even though the trench contact etch 124 may allow the Sxx stress 117 to relax as a free surface is present, for NMOS, the Sxx stress 117 relaxes far more than the Syy stress 119 as the free surface is horizontal (in the Sxx stress 117 direction).

After the contact material 125 is formed, there is no further significant stress relaxation beyond that seen during the contact etch 124. Importantly, this result is achieved without the need to develop additional stress relief films or the loss of the advantages of a TCN process. Additionally, the various embodiments of the present invention allow for a stress relief film to be used when salicide formation occurs in conjunction with the TCN process.

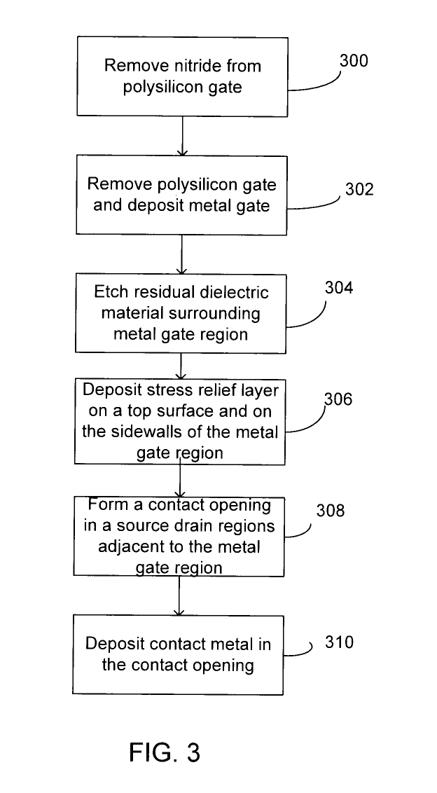

FIG. 3 depicts a flowchart according to another embodiment. At step 300, a nitride may be removed from a polysilicon gate. At step 302, the polysilicon gate may be removed and a metal gate may be formed. At step 304, a residual dielectric material may be etched from the surrounding metal gate region. At step 306, a stress relief layer may be deposited on a top surface and the sidewalls of the metal gate region. At step 308, a contact opening may be formed in a source drain region adjacent to the metal gate region, and at step 310, a contact metal may be formed in the contact opening.

Thus, the benefits of the embodiments of the present invention include, but are not limited to, etching remaining nitride/oxides left behind after the metal gate polish, and forming a stress relief layer to run not only across the metal gate but also down its sides, introducing the type of stress which enhances MOS performance. Additionally, a gate edge stop layer can be used in lieu of a new film to achieve this result. Moreover, this process is compatible with trench contact processes. Although TCN may lower the overall stress gain from the stressing layer, the resulting vertical stress component, which is the most desirable for (100) NMOS, will survive the TCN process.

Embodiments of the present invention enable reduction of external resistance of isolation bounded transistors. The stress relief film can be deposited on a PMOS device post nitride/oxide removal to further enhance PMOS performance. Both NMOS and PMOS devices benefit from use of the stress relief layer and exhibit drive performance gains of up to about 6% and 2% respectively.

Although the foregoing description has specified certain steps and materials that may be used in the method of the present invention, those skilled in the art will appreciate that many modifications and substitutions may be made. Accordingly, it is intended that all such modifications, alterations, substitutions and additions be considered to fall within the spirit and scope of the invention as defined by the appended claims. In addition, it is appreciated that certain aspects of microelectronic devices are well known in the art. Therefore, it is appreciated that the Figures provided herein illustrate only portions of an exemplary microelectronic device that pertains to the practice of the present invention. Thus the present invention is not limited to the structures described herein.

What is claimed is:

1. A method comprising:
removing residual dielectric material from a metal gate structure; and
forming a stress relief layer on a top surface and on a sidewall region of the metal gate structure, wherein a stress is introduced into a channel region disposed beneath the metal gate structure.

2. The method of claim 1 further comprising forming a trench opening in a source drain region disposed adjacent to the metal gate structure.

3. The method of claim 1 further comprising wherein the dielectric material comprises at least one of a nitride and oxide material.

4. The method of claim 1 further comprising wherein the stress relief layer comprises a thickness from about 5 nm to about 35 nm.

5. The method of claim 1 further comprising wherein the stress comprises a tensile stress.

6. The method of claim 1 further comprising wherein the structure comprises a metal gate transistor structure.

7. The method of claim 1 further comprising wherein the stress relief layer comprises a dual layer film.

8. The method of claim 6 further comprising wherein the metal gate transistor structure comprises a portion of at least one of a PMOS transistor and an NMOS transistor.

9. A method comprising:
forming a metal gate on the transistor structure;
etching residual dielectric material from the metal gate structure;
forming a stress relief layer on a top surface and on a sidewall of the metal gate structure, wherein a stress is introduced into a channel region disposed beneath the metal gate structure; and
etching a trench contact opening in a source drain region of the transistor structure.

10. The method of claim 9 further comprising wherein a contact metal is deposited in the trench contact opening.

11. The method of claim 9 further comprising wherein the stress relief layer comprises a gate edge stop layer.

12. The method of claim 9 further comprising wherein a polysilicon gate is removed from the transistor structure prior to the formation of the metal gate, and wherein the transistor structure comprises at least one of a PMOS and an NMOS transistor structure.

13. The method of claim 9 further comprising wherein the stress comprises a vertical stress.

14. The method of claim 1 further comprising wherein the stress relief layer comprises a thickness from about 5 nm to about 35 nm.

15. A structure comprising:
a stress relief layer on a top surface and on a sidewall region of a metal gate, wherein a channel region disposed beneath the metal gate comprises a stress.

16. The structure of claim 15 wherein the stress relief layer comprises a thickness of about 5 nm to about 35 nm.

17. The structure of claim 15 wherein the stress relief layer comprises a dielectric material.

18. The structure of claim 15 wherein the stress relief layer comprises a dual layer.

19. The structure of claim 15 wherein the structure comprises a portion of at least one of a PMOS and a NMOS transistor.

20. The structure of claim 15 wherein the structure further comprises a trench contact material disposed adjacent to the metal gate.
